(19) United States
(12) Patent Application Publication
(10) Pub. No.: US 2022/0285311 A1
(43) Pub. Date: Sep. 8, 2022

(54) Installing an Electronic Assembly

(71) Applicant: Siemens Aktiengesellschaft, München (DE)

(72) Inventors: Matthias Heimann, Potsdam (DE); Bernd Müller, Falkenberg (DE); Christian Nachtigall-Schellenberg, Potsdam (DE); Jörg Strogies, Berlin (DE); Klaus Wilke, Berlin (DE)

(73) Assignee: Siemens Aktiengesellschaft, München (DE)

(21) Appl. No.: 17/630,030

(22) PCT Filed: Jun. 15, 2020
(86) PCT No.: PCT/EP2020/066453

§ 371 Date: Jan. 25, 2022

(30) Foreign Application Priority Data
Jul. 30, 2019 (EP) 19189071.4

(51) Int. Cl. H01L 23/00; H01L 23/498; H01L 21/48; H01L 21/683

(52) U.S. Cl. CPC H01L 24/83; H01L 23/49811; H01L 21/4853; H01L 21/6835; H01L 23/49861; H01L 2221/68372; H01L 2224/83005; H01L 2224/83801; H01L 2224/8384; H01L 2224/32225; H01L 2224/32245; H01L 24/33; H01L 2224/33181; H01L 2924/13055; H01L 24/32

(57) ABSTRACT

Various embodiments include a method for installing an electronic assembly having a die and a substrate with a reference plane. The method may include: providing a product carrier having recesses with varying dimensions different from one another; and arranging planar molded parts, joining materials, and the die on the product carrier. The die is in electrical contact with at least one planar molded part and at least one joining material. The method further includes forming functional elements from the planar molded parts and/or the die and the joining materials, the functional elements supporting the substrate and electrically contacting the reference plane.

### CROSS-REFERENCE TO RELATED APPLICATIONS

This application is a U.S. National Stage Application of International Application No. PCT/EP2020/066453 filed Jun. 15, 2020, which designates the United States of America, and claims priority to EP Application No. 19189071.4 filed Jul. 30, 2019, the contents of which are hereby incorporated by reference in their entirety.

### TECHNICAL FIELD

The present disclosure relates to electronic assemblies. Various embodiments may include methods for installing an electronic assembly and/or electronic assemblies, e.g., power modules or components thereof.

### BACKGROUND

In some cases, an electronic assembly comprises a substrate with a reference plane and at least one die. A die is an unhoused semiconductor and is also referred to as a “bare die” or “naked chip”. The electrical contacting of the die with electrical connections of other components, further conductive structures or with electrical connections of a housing usually takes place via wire bonding in the prior art. In some instances, wire bond-free technologies (e.g., leadframe, films, ball bonding) are used.

### SUMMARY

The teachings of the present disclosure include methods for installing electronic assemblies which simplify the electrical contacting of dies during their installation. For example, some embodiments include a method for installing an electronic assembly (10) having at least one die (40) and a substrate (150) with a reference plane (152), the method comprising: providing a product carrier (200) which has one or a plurality of recesses (220, 221) with dimensions which are different from one another, arranging the planar molded parts (21, . . . , 24), joining materials (30) and the at least one die (40) on the product carrier (200) so that the die (40) is electrically contacted with at least one of the planar molded parts (21, . . . , 24) and one of the joining materials (30), and functional elements (61, 62, 63) are formed from the planar molded parts (21, . . . , 24) and/or the die (40) as well as the joining materials (30), which functional elements are designed for supporting the substrate (150) and for electrically contacting the reference plane (152).

In some embodiments, the functional elements (61, 62, 63) are formed spaced apart from one another.

In some embodiments, the method further comprises providing one or a plurality of auxiliary elements (228), in particular on a product carrier (200).

In some embodiments, the method further comprises positioning the substrate (150) on the functional elements (61, 62, 63) so that the reference plane (152) is electrically contacted with the functional elements (61, 62, 63).

In some embodiments, at least one of the molded parts (21, . . . , 24) used for contacting the die (40) is designed as a leadframe.

In some embodiments, the method further comprises arranging electrically insulating elements so that electrically insulated supporting points are formed for the substrate (150).

In some embodiments, the method further comprises joining so that the joining materials (30) form connections with the molded parts (21, . . . , 24), the die (40) and/or the reference plane (150).

In some embodiments, at least one electrical component is arranged.

In some embodiments, the arrangement of the planar molded parts (21, . . . , 24) and/or the joining materials (24) is carried out in layers.

As another example, some embodiments include an electronic assembly (10) having at least one die (40), a substrate (150) with a reference plane (152) and functional elements (61, 62, 63), wherein the die (40) is electrically contacted with at least one of the molded parts (21, . . . , 24) and one of the joining materials (30), wherein the functional elements (61, 62, 63) are formed from molded parts (21, . . . , 24) and/or the die (40) as well as joining materials (30), and are designed for supporting the substrate (150) and for electrically contacting the reference plane (152).

### BRIEF DESCRIPTION OF THE DRAWINGS

The teachings herein are explained in greater detail hereinafter using the exemplary embodiments represented in the figures. In the figures:

FIG. 1 shows a product carrier with a support structure arranged thereon incorporating teachings of the present disclosure;

FIG. 2 shows an exploded view of a support structure incorporating teachings of the present disclosure;

FIG. 3 shows a further embodiment of a product carrier incorporating teachings of the present disclosure;

FIG. 4 shows a support structure in cooperation with a substrate incorporating teachings of the present disclosure;

FIG. 5 shows an electronic assembly incorporating teachings of the present disclosure; and

FIG. 6 shows one possible further production step incorporating teachings of the present disclosure.

### DETAILED DESCRIPTION

Various embodiments of the teachings herein include a method for installing an electronic assembly, wherein the assembly has at least one die and a substrate with a reference plane. For installation, planar molded parts, joining materials and the at least one die are arranged in such a way that: the die is electrically contacted with at least one of the planar molded parts and one of the joining materials, and functional elements are formed from the molded parts and/or the die as well as the joining materials, which functional elements are designed for supporting the substrate and for electrically contacting the reference plane. In some embodiments, a plurality of functional elements are formed, since a plurality of functional elements can better support the substrate. If a plurality of dies are contacted, more functional elements are correspondingly provided for contacting the dies and the support function is further improved.

Planar molded parts are planar parts made of an electrically conductive material which can be produced in a cost effective manner. In this case, the planar molded parts are produced without bending processes, can be stamped from sheet metal, for example, and can be fed in variable shape and thickness, for example as bulk material or rolled up as tape, to a product carrier which can be fitted automatically. The molded parts are generally cuboidal or plate-shaped. However, the molded parts can also be discoidal or have other flat geometries. A height adjustment of the molded parts can take place during the normal joining process (for example by means of soldering or sintering) through layers of the materials required for this. In this case, the molded parts may be copper molded parts. The dimensioning of the molded parts may depend on the maximum current which is to be conducted. The molded parts are generally between 300 μm and 2 mm thick and can have variable other dimensions.

Solder materials and/or sinter materials can be used as joining materials in the form of printable or dispensable pastes or as solder preforms or sintered molded parts in each case. In this case, the arrangement of the planar molded parts can be carried out by automatic placement machines on a product carrier.

During installation, the functional elements form mechanically stable units and are designed for supporting the substrate during the installation process. It is possible for the functional elements to undergo a joining process (for example thermal joining) before the substrate is positioned on the functional elements. This means that the functional elements can form one or a plurality of mechanically inherently stable units for the purpose of further installation, which improves the further manageability of the functional elements. It is also possible to join the functional elements together with the substrate.

The functional elements form a support structure which is configured in such a way that a substrate can be positioned thereon for further installation of the assembly. In this case, the support structure can be configured in such a way that it completely carries the substrate. The functional elements therefore unite two functions, supporting and contacting, in one element. The methods described herein, therefore, offer the potential to realize all connection levels for producing the product in only one process. Furthermore, the functional elements can be set up in an electrically and thermally optimum manner as a result of the variable planar molded parts. This may be carried out in stacks. Various embodiments simplify the contacting of the dies and therefore enable further degrees of freedom in the structure of the assembly.

If the substrate has been positioned on the functional elements and a joining process has been completed, the functional elements form a permanent electrical and mechanical connection with the substrate or the reference plane thereof. The functional elements are therefore connected to the substrate in a mechanical manner, the support function has thus served its purpose and the function of the electrical contacting is now in the foreground.

In some embodiments, the method includes providing a product carrier, wherein the molded parts, dies and/or joining materials are arranged on the product carrier. In this case, the product carrier can have one or a plurality of recesses, wherein the molded parts, dies and/or joining materials can then be arranged in such a way that at least one part of the functional elements is formed in the recesses. In this case, the molded parts can be arranged directly, i.e. without further intermediate elements, on the product carrier. In this case, the product carrier is primarily used to transport the assembly and its functional elements through the production process. In this case, the recesses can also be configured in such a way that they provide a support function for the functional elements which have not yet been joined.

The product carrier does not remain on the completed assembly. It is possible for a product carrier to already be pre-fitted with a first layer of selected molded parts. In this case, a product carrier can have a tablet-like design or in this case can also be designed as part of a conveyor belt system or otherwise, for example a (semi-) autonomous conveyor system. The use of a product carrier increases the manageability of the present methods. In other words, an intelligent product carrier concept is made available, on the basis of which the joining partners are set up additively in a fully automated manner, for example by way of intelligent layering and joining. It may be advantageous if the product carrier is configured in such a way that the functional elements substantially form a plane. Other forms are then conceivable and useful if no flat substrates are to be used.

In some embodiments, the functional elements are designed to be spaced apart from one another. The functional elements are arranged spaced apart from one another, i.e. arranged in such a way that they can perform a support function on a plurality of points of a substrate which is positioned thereon. This makes it possible to achieve an even distribution of the load with respect to the substrate. The functional elements can be arranged in such a way that they can completely carry the substrate during the installation process. Furthermore, the functional elements are arranged in such a way that the electrical contacting of the functional elements and the substrate can be realized.

In some embodiments, the product carrier has one or a plurality of recesses with dimensions which are different from one another. This can include, for example, a different depth of the recesses, for example in order to compensate for height differences. Furthermore, the product carrier can have recesses which are adapted to specific molded parts. The depth of the recess corresponds to the thicknesses of the molded parts arranged there and/or to the necessary height adjustment. The depth of the recesses is generally no more than 2 mm but may be above this if particularly thick parts are to be processed.

In some embodiments, the method includes arranging one or a plurality of auxiliary elements. The auxiliary elements can be arranged on a product carrier and/or below molded parts. In this case, the auxiliary elements do not remain permanently in the electronic assembly, but rather are removed again if the auxiliary elements have served their purpose—for example intermediate provision of a mechanical support function or a support function for a delicate component. The auxiliary elements can therefore remain on the product carrier and can compensate for a greater height difference than the product carrier and in this case contribute to increasing the flexibility. Alternatively or additionally, auxiliary elements can only be removed later on in the process. The auxiliary elements themselves can, in turn, have recesses or already be pre-fitted with components.

In some embodiments, the method includes positioning the substrate on the functional elements so that the reference plane is electrically contacted with the functional elements. In other words, conductive structures of the electrical assembly, which were previously still divided between the reference plane of the substrate and the functional elements, are completed by electrically contacting the reference plane with the functional elements. Positioning the substrate on the functional elements completes the conductive structures of the assembly and they can be joined. In this case, the substrate may have a structured reference plane and may already have further electronic components. This allows the functional elements to be set up with great complexity and independently of the substrate and the substrate can only be subsequently applied to functional elements. This enables high degrees of freedom in the design of the electronic assembly.

In some embodiments, at least one of the molded parts used for contacting the die is designed as a leadframe. This embodiment makes a production process possible which integrates the connection of leadframes into the installation process, thus enabling greater scope for design and potentially spares a separate installation/process step. Combinations with standardized leadframe structures (for example in a pre-molded variant) are also conceivable in which product-specific adaptations take place by way of downstream processing (for example laser cuts for removing support structures or wiring layers which are not used). The leadframe technology offers advantages for the wiring of dies owing to the power cycling strength and the electrical performance (electrical and thermal conductivity, low inductance, etc.). Previously, this technology was not economically feasible due to the initial cost for small quantities (tools for stamping, forms and molds, etc.). The cost increases with the complexity and the accuracy requirements of the leadframe (different potentials, variable leadframe cross sections, etc.).

In some embodiments, the method includes arranging the leadframe and the molded parts in such a way that a unit is formed from the leadframe, the molded parts and the joining materials which is manageable within the context of installation. Manageable here means that the unit has at least one sufficient mechanical cohesion, so that it does not collapse into individual parts again during the further process steps. For this purpose, a joining step can be carried out, for example, which forms a unit from the functional elements. For example, parts of the joining materials can be joined (for example by sintering or soldering).

In some embodiments, the method includes arranging electrically insulating elements so that electrically insulated supporting points are formed for the substrate. This allows molded parts of different potentials to be insulated and mechanically stabilized via electrically insulating molded parts at suitable supporting points. The production of electrically conductive connections between differently shaped molded parts of variable thickness is also possible as a result of using local wiring carrier. In this way, the functional elements can be relieved and the scope for design is further increased. The electrically insulating elements preferably remain in their function as an electrical insulator on the assembly.

In some embodiments, the method includes joining so that the joining materials form connections with the molded parts, the die and/or the reference plane. In this case, the joining can connect both the molded parts and the die with the joining materials. Soldering and sintering methods are conceivable in this case. The joining methods can henceforth be carried out simultaneously for all functional elements and the substrate and in one single process step. If necessary, it is also conceivable, if, for example, functional elements which are particularly robust or are equipped with high current-carrying capacity are required, for a multi-part joining method to be carried out, a plurality of joining methods are combined. For example, firstly a sintering method which generates high temperature resistant sinter connections for the die, and subsequently a soldering method which connects the substrate.

In some embodiments, the method includes arranging at least one further electrical assembly. This may occur in addition to the arrangement of the molded parts, the dies and the joining materials and can be carried out in the same process step. Passive and/or active components can be arranged in this case. In some embodiments, further components are processed with the molded parts. This can be a current measurement shunt, for example, which measures the current in close proximity to the die. This means that in addition to the production of conductive connections and structures, functional elements can already be established in the immediate vicinity of the die.

In some embodiments, the arrangement of the planar molded parts and/or the joining materials is carried out in layers. It has proven to be advantageous to carry out the arrangement of the molded parts and the joining materials in layers, since in this way quality control is already possible in the individual layers of the arrangement, for example, and if there are errors or defects in one layer, measures can be taken without further ado.

In some embodiments, an electronic assembly has at least one die, a substrate with a reference plane and a plurality of functional elements which are arranged spaced appart from one another. The die is electrically contacted with at least one of the molded parts and one of the joining materials. The functional elements are at least partially formed from molded parts and/or the die as well as joining materials, wherein the functional elements are designed for supporting the substrate, in particular during production and for electrically contacting the reference plane. In this case, the PCB may have active components which form a so called “control unit” and provide the control logic for controlling the dies.

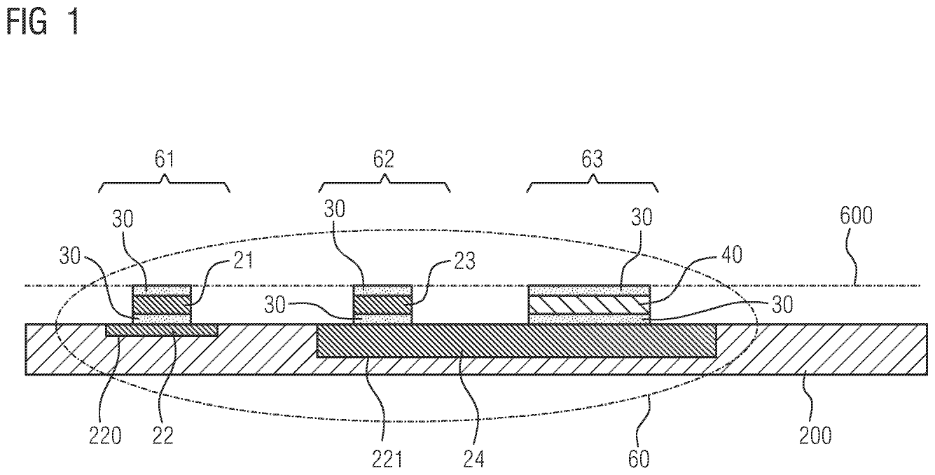

FIG. 1 shows a product carrier 200 in which functional elements 61, 62, 63 have been arranged. In this case, the functional elements 61, 62, 63 form a support structure 60. Furthermore, the functional elements 61, 62, 63 form a contact surface 600 of the support structure 60 which in this case is designed as a plane and in order to support a substrate 150, which is not shown here, in the next process steps. The product carrier 200 has two recesses 220 and 221, wherein the support element 61 is arranged in the recess 220 and the functional elements 62 and 63 which are based on a common base are arranged in the recess 221. In this case, the support element 61 has molded parts 21, 22 and joining materials 30. In this case, the support element 62 has molded parts 23 and a part of the molded part 24 as well as joining materials 30. A die 40, for example a semiconductor switch such as an IGBT bare die, is arranged on the molded part 24 with joining materials 30, such that the die 40 forms a support element 63. At the same time, the die upper side and the die lower side has been brought onto a common plane (the plane of the contact surface 600) by means of the common base, the molded part 24. A contacting of dies can therefore be greatly simplified.

It should be noted that the molded parts 21, . . . , 24 are arranged directly on the product carrier 200 and are not applied to a substrate. This type of arrangement enables greater flexibility and significantly more degrees of freedom in the structure of the contact structures which are to be connected to a substrate.

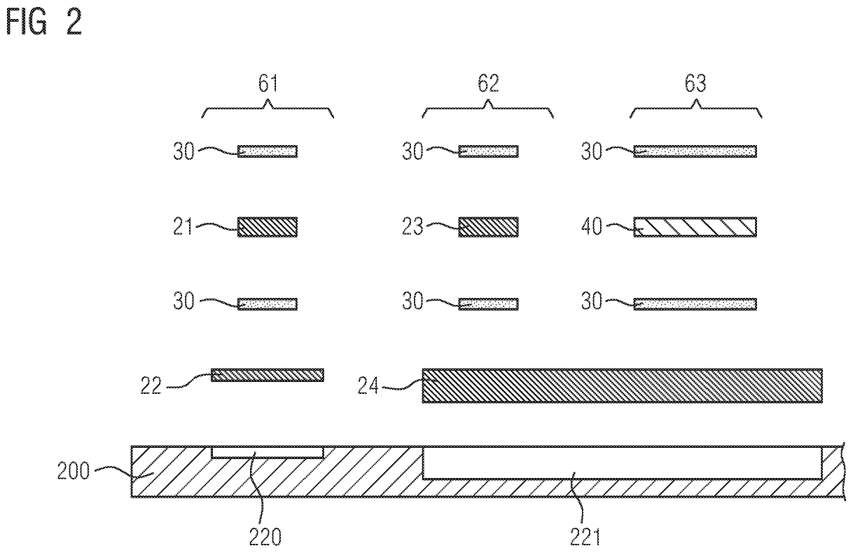

FIG. 2 shows an exploded view of the functional elements 61, 62, 63 or the support structure 60 as it is known from FIG. 1. In this case, the support element 61 is arranged in stacks made up of a copper molded part 22 which is inserted into the recess 220, a joining material 30, a further copper molded part 21 as well as a final further joining material 30. In this case, the molded part 21 is a very flat copper molded part, in comparison, a significantly thicker and wider copper molded part 24 is inserted into a recess 221. The different thicknesses are in the present case compensated by different depths of the recesses 220, 221. The copper molded part 24 serves as a base for two further functional elements 62, 63 which are consequently electrically connected via the copper molded part 24. In this case, the dimensions of the molded parts can be selected based on thermal and power criteria. The joining materials 30 can also be adapted to their molded parts. It is therefore conceivable for special bracket materials 30 to be used for them in this case, whereas further joining materials 30 are used for the copper molded parts 21, . . . , 24.

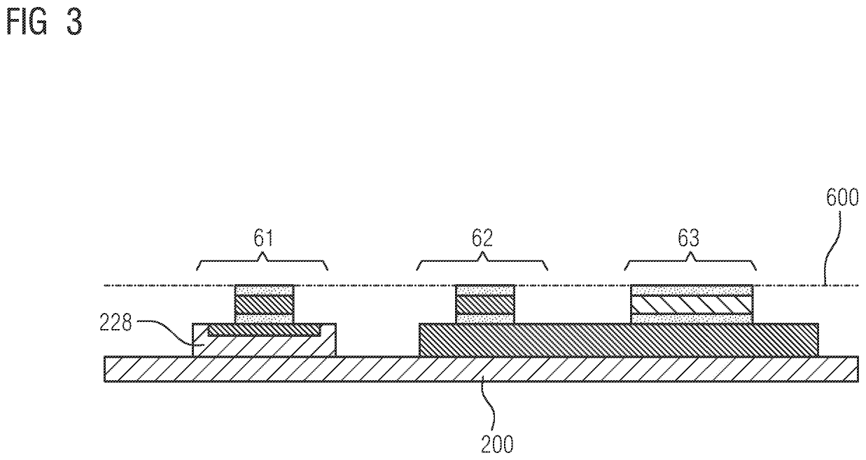

FIG. 3 shows one further embodiment of a product carrier 200, wherein it does not have any recesses, but rather, by means of an auxiliary element 228, makes a height adjustment between the functional elements 61, 62 and 63, as they are known from FIGS. 1 and 2. The auxiliary element 228 may already have first molded parts or prefabricated functional elements and can be made available directly, if, in other words, the auxiliary element 228 is already supplied with molded parts and then arranged together with further molded parts 21, . . . , 24 on the product carrier 200, for example with an automatic placement machine. However, it is also conceivable that the auxiliary element 228 is designed as part of the product carrier 200. As shown in the preceding FIGS. 1 and 2, the contact surface 600 remains level.

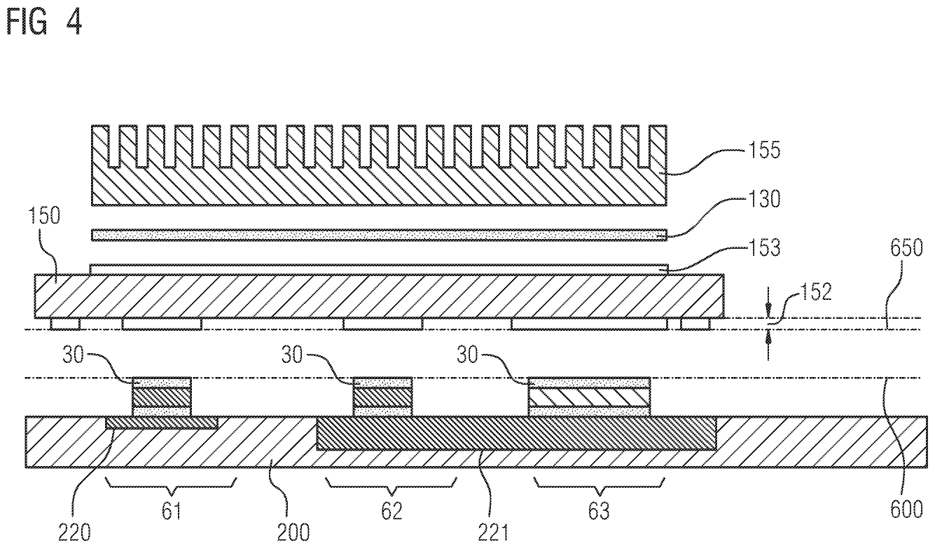

FIG. 4 shows how the support structure 60 cooperates with a substrate 150. The substrate 150 has a reference plane 152 which is already structured in this case. On the upper side of the substrate 150, a lamination 153 is provided which serves to connect a heat sink 155 to the substrate 150 by means of a heat sink joining material 130. The substrate 150 or the reference plane 152 includes a contact surface 650 of the reference plane 152. In this case, the contact surface 650 of the reference plane 152 is configured in such a way that it can be placed onto the contact plane 600 of the support structure 60. In other words, the functional elements 61, 62, 63 are configured or designed in relation to the reference plane 152 in such a way that they can realize their support function and the electrical contacting of the die 40. It should be mentioned at this point that the support function applies to the production process. If a joining process, for example soldering and/or sintering, has been carried out, this support function is, for the most part, no longer necessary and the functional elements 61, 62, 63 mainly serve their second function of electrical contacting, in particular of the die 40.

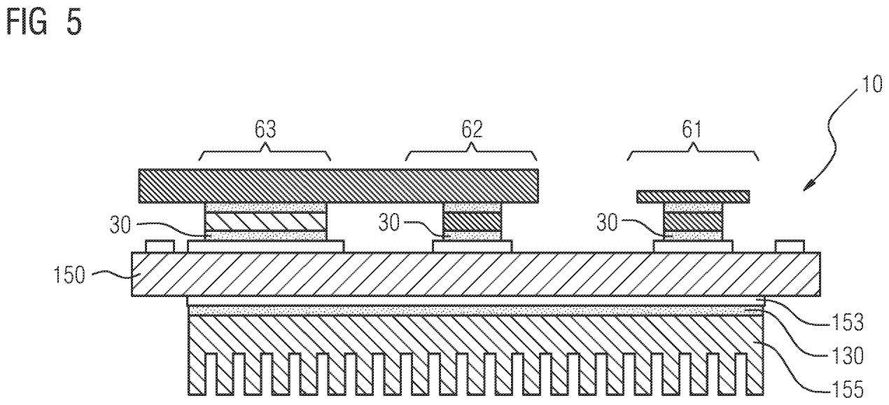

FIG. 5 shows the completed electronic assembly 10 as it has been installed in FIG. 4. In this case, the assembly 10 has been removed from the product carrier 200 and has been turned around for further processing. The orientation shown in this figure corresponds in this case to the orientation in which electronic assemblies are usually fitted. The method according to the invention enables more degrees of freedom in this case by the functional elements 61, 62, 63 being arranged independently of the substrate 150 and therefore can be set up in an optimum manner, for example with respect to temperature and/or electrical power. By way of example, the assembly 10 shown in FIG. 5 can be set up with the following method:
providing a product carrier 200, wherein the molded parts 21, . . . , 24, dies 40 and/or joining materials 30 are arranged on the product carrier 200 in such a way that
the die 40 is electrically contacted with at least one of the planar molded parts 21, . . . , 24 and one of the joining materials 30,
functional elements 61, 62, 63 are formed from the planar molded parts 21, . . . , 24 and/or the die 40 as well as the joining materials 30, which functional elements are designed for supporting the substrate 150 and for electrically contacting the reference plane 152,
joining so that the joining materials 30 form connections with the molded parts 21, . . . , 24, the die 40 and/or the reference plane 152 and finally
turning the assembly 10 for further processing.

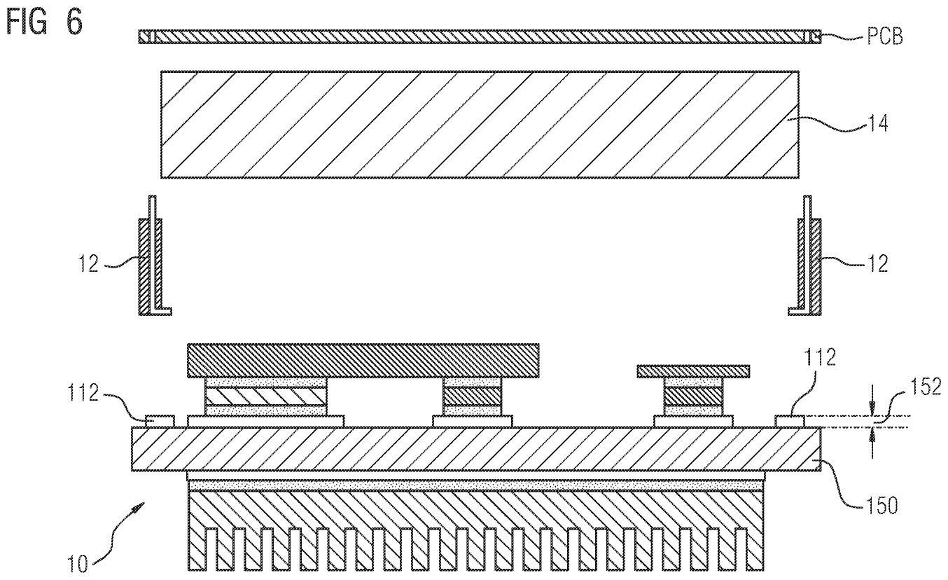

FIG. 6 shows one possible further production step of the electrical assembly 10 from FIG. 5. The structured reference plane 152 of the substrate 150 has contacts 112 for a frame 12 with pins. If the frame 12 with pins is connected to the electrical assembly 10, a potting material 14 can be poured in, in order to make it possible to protect the electronic assembly 10 and the components arranged thereon. A control electronics PCB, in this case designed as a printed circuit board, can subsequently be contacted and is designed for controlling a power electronics which has been produced with the methods described herein, for example.

In summary, some embodiments include a method for installing an electronic assembly 10 having a die 40 and a substrate 150 with a reference plane 152. Some embodiments include arranging planar molded parts 21, . . . , 24, joining materials 30 and the at least one die 40 so that the die 40 is electrically contacted with at least one of the planar molded parts 21, . . . , 24 and one of the joining materials 30, and functional elements 61, 62, 63 are formed from the planar molded parts 21, . . . , 24 and/or the die 40 as well as the joining materials 30, which functional elements are designed for supporting the substrate 150 and for electrically contacting the reference plane 152.

### LIST OF REFERENCE NUMBERS

10 electronic assembly
12 frame with pins
14 potting material
PCB control electronics
21, 22, 23, 24 planar molded parts
26 insulating molded parts
30 joining materials
40 die
60 support structure
61, 62, 63 functional elements
150 substrate
152 reference plane
200 product carrier
220, 221 recesses
228 auxiliary element
600 contact surface
650 contact surface of the reference plane

What is claimed is:

1. A method for installing an electronic assembly having a die and a substrate with a reference plane, the method comprising:
providing a product carrier having recesses with varying dimensions different from one another;
arranging planar molded parts, joining materials, and the die on the product carrier;
wherein
the die is in electrical contact with at least one of the planar molded parts and at least one of the joining materials; and
forming functional elements from the planar molded parts and/or the die and the joining materials, the functional elements supporting the substrate and electrically contacting the reference plane.

2. The method as claimed in claim 1, wherein the functional elements are spaced apart from one another.

3. The method as claimed in claim 1, further comprising providing an auxiliary element on a product carrier.

4. The method as claimed in claim 1, further comprising positioning the substrate on the functional elements so that the reference plane is in electrical contact with the functional elements.

5. The method as claimed in claim 1, wherein at least one of the molded parts used for contacting the die comprises a leadframe.

6. The method as claimed in claim 1, further comprising arranging electrically insulating elements so that electrically insulated supporting points are formed for the substrate.

7. The method as claimed in claim 1, further comprising joining so that the joining materials form connections with the molded parts, the die, and/or the reference plane.

8. The method as claimed in claim 1, further comprising arranging an electrical component.

9. The method as claimed in claim 1, wherein the arrangement of the planar molded parts and/or the joining materials is carried out in layers.

10. An electronic assembly comprising:
a die;
a substrate with a reference plane; and
functional elements;
wherein the die is in electrical contact with a molded part and a joining material;
wherein the functional elements are formed from the molded part and/or the die as well as the joining material and support the substrate and electrically contact the reference plane.
